(19) United States
(12) Patent Application Publication
(10) Pub. No.: US 2010/0117542 A1
(43) Pub. Date: May 13, 2010

(54) LED LIGHT PIPE ORNAMENT

(75) Inventor: Victoria Jean Van Dyn Hoven, Stevens Point, WI (US)

Correspondence Address: RATHE PATENT & IP LAW, 10611 W. HAWTHORNE FARMS LANE, MEQUON, WI, 53097, US

(73) Assignee: Vickie Jean's Creations, Inc., Plover, WI (US)

(21) Appl. No.: 12/615,256

(22) Filed: Nov. 9, 2009

Related U.S. Application Data
(60) Provisional application No. 61/112,750, filed on Nov. 8, 2008.

(51) Int. Cl. H05B 37/02; H01L 33/00; F21V 3/00

(52) U.S. Cl. 315/149; 362/555; 362/311.13; 362/183; 362/565

(57) ABSTRACT

A LED light pipe ornament assembly includes a light emitting diode, a light pipe and a translucent silicone ornament mounted on the light type to radiate light received from the light pipe.

### CROSS-REFERENCE TO RELATED PATENT APPLICATIONS

The present the present application claims priority under 35 USC 119(e) from co-pending U.S. Divisional patent application Ser. No. 61/112,750 filed on Nov. 8, 2008 by Victoria Jean Van Dyn Hoven and entitled LED LIGHT PIPE ORNAMENT, the full disclosure of which is hereby incorporated by reference.

### BACKGROUND

Ornaments are sometimes lit and supported by an incandescent light bulb. Such ornaments consume large amounts of energy and may require that ornament be discarded when the light bulb burns out.

### BRIEF DESCRIPTION OF THE DRAWINGS

FIG. 1 is a top perspective view of an ornament kit having an ornament assembly and an exchangeable ornament according to an example embodiment.

FIG. 2 is a fragmentary sectional view of the ornament assembly of FIG. 1.

FIG. 3 is an exploded perspective view of the ornament assembly of FIG. 1.

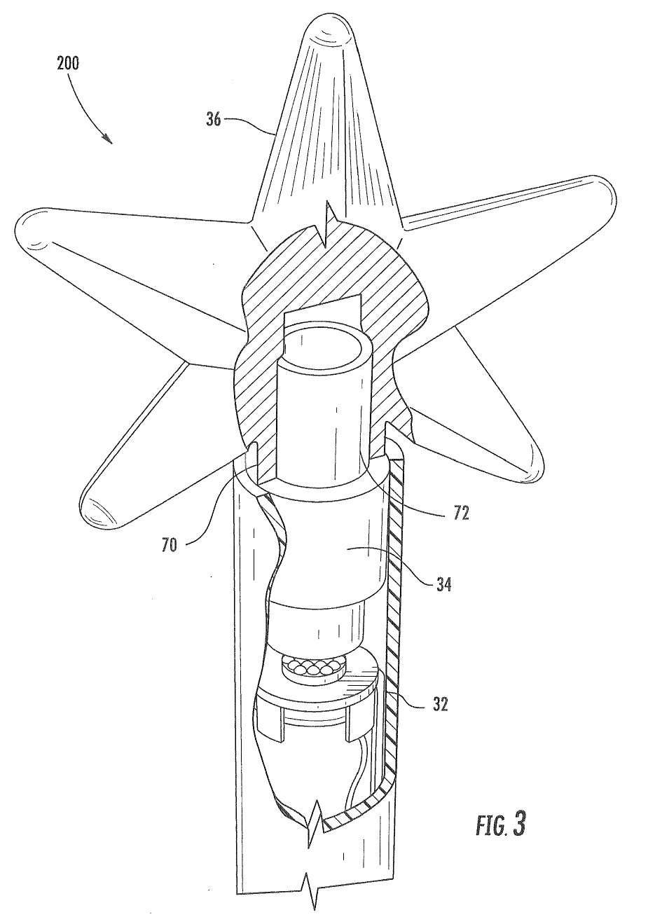

### DETAILED DESCRIPTION OF THE EXAMPLE EMBODIMENTS

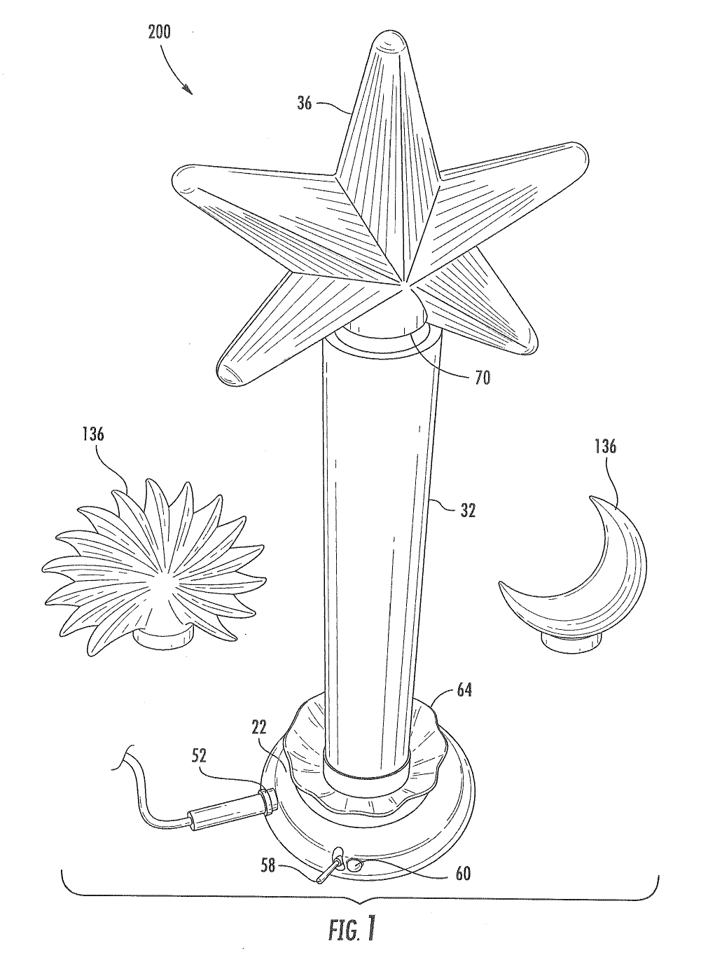

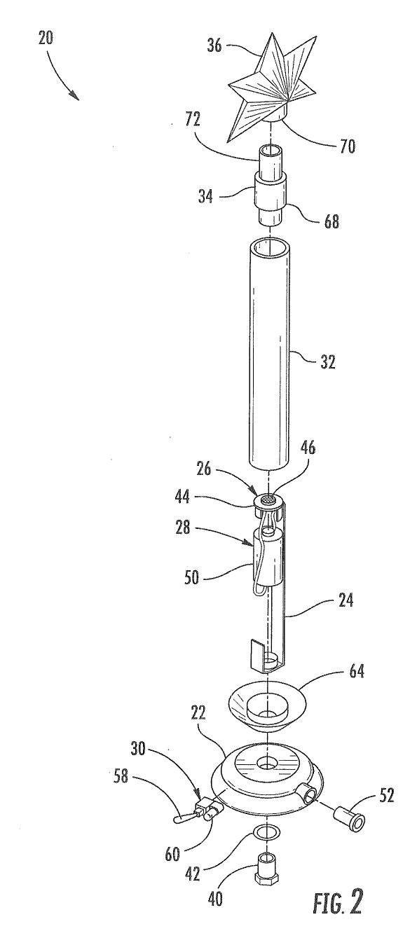

FIGS. 1 and 2 illustrate an ornament assembly 20 according to an example embodiment. FIG. 1 is a top perspective view of ornament assembly 20. FIG. 2 is an exploded perspective view of ornament 20. Ornament assembly 20 includes base 22, frame and 24, light emitting diode assembly 26, power source 28, switch 30, housing 32, light pipe 34 and ornament 36. As will be described hereafter, ornament assembly 22 illuminates and supports ornament 36 in a more efficient manner, allowing ornament 36 to be more easily exchanged or replaced.

Base 22 supports ornament assembly 20. In one embodiment, base 22 is formed from wood. In another embodiment, base 22 may be formed other materials may be formed from other materials or from more than one structure. In yet other embodiments where ornament assembly 20 is supported or mounted to a surface in other fashions, such as by a clip or the like, base 22 may be omitted.

Frame 24 comprises one or more structures configured to support housing 32 with respect to base 22 and to further support portions of the power source 28 and light emitting diode assembly 26. In the example illustrated, frame 24 is fastened to base 22 using fasteners 40 and 42 comprising a threaded bushing and a lock washer, respectively. In other embodiments, frame 24 may be secured to base 22 in other fashions.

Light emitting diode assembly 26 comprises a printed circuit board 44 supporting one or more light emitting diodes 46. Light emitting diode assembly 26 is mounted onto and supported by frame 24 within housing 32. In other embodiments, light emitting diode assembly 26 or at least its one or more lightning diodes 46 may at least partially project beyond housing 32.

Power source 28 comprises a source of power for the one or more light emitting diodes 46. In the example illustrated, power source 28 comprises a rechargeable battery 50 wired to light emitting diode assembly 26 and a power jack 52. Battery 50 is configured to be recharged using power jack 52. In the example illustrated, power jack 52 comprises a 6 V DC jack. In other embodiments, power jack 52 may comprise other ports or couplings for recharging battery 50. In yet other embodiments, rechargeable battery 50 and jack 52 may be replaced with one or more disposable non-rechargeable batteries. For example, base 22 may include an opening allowing insertion of one or more such disposal batteries in an end-to-end fashion. In such embodiments, such batteries may be contained within housing 32.

Switch 30 comprises a mechanism by which power is controllably supplied to light emitting diode assembly 26. In one embodiment, switch 30 includes a manual switch component 58 and a photodetector switch element 60. Manual switch component 58 enables a person to manually turn the one of more light emitting diodes 46 on or off. In some embodiments, component 58 may have additional positions, allowing diodes 46 to be actuated between two different light emitting colors or light emitting brightnesses or states, such as a dim state and a bright state.

Photodetector switch element 60 comprises a photo transistor or other device which senses ambient light and which automatically actuates the one or more light emitting diodes 46 to different states. For example, in one embodiment, photodetector switch element 60 may automatically turn light emitting diodes 46 on in response to ambient light falling below low light thresholds. Switch element 60 may further automatically turn off light emitting diodes 46 in response to ambient light exceeding certain light thresholds. In one embodiment, manual switch component 58 may be used to override the automatic operation provided by photo detector 60. In other embodiments, switch 30 may comprise other light emitting diode actuation mechanisms or may omit either of component 58 or detector 60.

Housing 32 comprises a body configured to support light type 34 and ornament 36. In the example illustrated, housing 32 comprises an elongate tube, providing the appearance of a candle shaft or candle body. In one embodiment, housing 32 comprises a tube formed from one or more heat resistant materials such as a cardboard or paperboard material. Housing 32 receives and encloses frame 24, light emitting diode assembly 26 and battery 50.

Printed circuit board 44 and light emitting diodes 46 are all completely surrounded and contained within the tube of housing 32. Light emitted by light emitting diodes 46 is directed through the tube of housing 32 to light pipe 34. Housing 32 serves as an opaque shroud about a portion of light pipe 34 and about the one or more light emitting diodes 46. In other embodiments, housing 32 may have other configurations. In the example illustrated in which ornament is to represent or depict a candle having an illuminated ornament at its top, assembly 20 additionally includes a flower 64 which simulates a corrugated drip holder. In other embodiments, flower 64 may be omitted.

Light pipe 34 comprises one or more structures configured to transmit light from light emitting diode 46 and to disperse such light throughout ornament 36. At the same time, light pipe 34 is configured to provide a mounting surface upon which ornament 36 may be mounted and supported. In the example illustrated, light pipe 34 if configured (shaped and dimensioned) such that ornament 36 may removably slide onto and off of light pipe 34 without damage to ornament 36 or light pipe 34. As a result, ornament 36 may be exchanged with other ornaments having other configurations, providing assembly 20 with greater versatility. In the example illustrated, ornament 36 is removably mounted on light pipe 34 by friction. In the example illustrated, light pipe 34 comprises a rod of transparent light conducting material, such as Lucite. In the example illustrated, light pipe 34 includes a shoulder 68 facilitate in retention of light pipe 34 with respect to housing 32. In other embodiments, light type 34 may have other configurations and maybe far from other light conducting or transmitting materials.

In the example illustrated, light pipe 34 is mounted or supported at an end of housing 32 and receives light that is passed through housing 32 from the one or more light emitting diodes 46. Light pipe 34 projects beyond a center point of ornament 36 for faster solution of light throughout ornament 36. In other embodiments, light pipe 34 may alternatively include a cavity or opening that receives the one of more light emitting diodes 46, wherein light pipe 34 disperses, distributes and transmits the light from diodes 46 to and throughout ornament 36. In still other embodiments, light pipe 34 may be omitted, wherein the one of more lightning diodes 46 are located within an interior of ornament 36.

Ornament 36 comprises a translucent ornament configured to radiate light received from light pipe 34. Ornament 36 may be formed from a generally heat resistant material. In the example illustrated, ornament 36 is configured to be removably mounted onto light pipe 34. For purposes of this disclosure, the term “removably” means that the ornament may be completely separated from light pipe 34 without damaging or permanently altering the ornament 36 or the light pipe 34. According to one embodiment, ornament 36 is integrally formed as a single unitary body from silicone. In particular embodiments, ornament 36 may be colored, may be scented or may include embedded particulates or other objects.

In the example illustrated, ornament 36 includes an interior cavity 70 configured to receive a connecting portion 72 of light pipe 34. In one embodiments, cavity 70 is dimensioned or sized slightly smaller than portion 72, wherein ornament 36 is formed from a resiliently flexible material, such as silicone, enabling a mouth of the cavity 70 to resiliently stretch and widen when receiving portion 72. This resilient nature of cavity 70 retains ornament 36 on light pipe 34 but allows ornament 36 to be removed without damaging ornament 36.

In other embodiments, ornament 36 may be permanently fixed, mounted, glued, bonded or welded to light pipe 34. In yet other embodiments, ornament 36 may be removably mounted to housing 32 in lieu being mounted to light pipe 34. In still other embodiments, ornament 36 may be permanently fixed, mounted, glued, bonded or welded to housing 32/to receive light transmitted through housing 32 or so as to at least partially enclose the one or more diodes 46.

As shown by FIG. 1, additional ornaments 136 may also be provided with assembly 22 form a kit 200. Ornaments 136 are similar to ornament 36 except ornaments 136 have different shapes extending from cavity 70. As a result, a person may remove ornament 36 and instead mount one of ornaments 136 to light pipe 34. A person may exchange ornament 36 and ornaments 136 as desired to accommodate different seasons, holidays or preferences. The remaining portions of assembly 20 can be used for both displays provided by the different ornaments.

What is claimed is:

1. An LED light pipe ornament assembly comprising:
a light emitting diode;
a light pipe configured to transmit light from the light emitting diode; and
a translucent silicone ornament mounted on the light pipe and configured to radiate light received from the light pipe.

2. The ornament assembly of claim 1, wherein the silicone ornament is removably mounted on the light pipe by friction.

3. The ornament assembly of claim 1, wherein a first portion of the light pipe is received within the ornament and wherein the ornament further comprises an opaque shroud about a second portion of the light pipe and about a light emitting diode.

4. The ornament assembly of claim 1, where the light pipe has a recess receiving the light emitting diode.

5. The ornament assembly of claim 1, wherein the light pipe comprises a LUCITE rod.

6. The ornament assembly of claim 1 further comprising a tube receiving a light pipe and the light emitting diode, when the ornament is supported at an end of the tube.

7. The ornament assembly of claim 1 further comprising a battery received within the tube and electrically connected to the light emitting diode.

8. The ornament assembly of claim 7, wherein the battery is rechargeable.

9. The ornament assembly of claim 1 further comprising a light sensor configured to detect ambient light, wherein the light emitting diode is powered in response to detecting ambient light being below a predetermined threshold.

10. The ornament assembly of claim 1, wherein the light pipe projects beyond a center point of the ornament.

11. The ornament assembly of claim 1, wherein the silicone ornament is integrally formed as a single unitary body from silicone.

12. The ornament assembly of claim 1, wherein the ornament has a silicone mouth smaller than the light pipe so as to resiliently flex during reception of the light pipe.

13. The ornament assembly of claim 1, wherein the silicone ornament is colored.

14. The ornament assembly of claim 1, wherein the silicone ornament is scented.

15. The ornament assembly of claim 1 further comprising:
a base;
a corrugated drip holder at the base; and
a tube projecting from the drip holder and supported by the base, the tube simulating a candlestick, wherein the light emitting diode and a first portion of the light pipe is received within the tube and wherein a second portion of the light pipe projects beyond the tube and is received within the silicone ornament.

16. An LED ornament assembly comprising:
a light emitting diode;
a housing supporting the light emitting diode; and
a translucent silicone ornament mounted on housing about the light emitting diode and configured to radiate light received from the light emitting diode.

17. The ornament assembly of claim 16, wherein the housing comprises a tube and wherein the ornament assembly further comprises a battery received within the tube and electrically connected to the light emitting diode.

18. The ornament assembly of claim 7 further comprising a light pipe removably received within a mouth of the ornament and configured to transmit light from the light emitting diode into the ornament.
